(19) United States
(12) Patent Application Publication
(10) Pub. No.: US 2024/0324249 A1
(43) Pub. Date: Sep. 26, 2024

(54) STORAGE DEVICE

(71) Applicant: Kioxia Corporation, Tokyo (JP)

(72) Inventor: Kouji MATSUO, Ama Aichi (JP)

(21) Appl. No.: 18/595,303

(22) Filed: Mar. 4, 2024

(30) Foreign Application Priority Data
Mar. 23, 2023 (JP) 2023-046743

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08145; H01L 2924/1431; H01L 2924/14511

(57) ABSTRACT

A plurality of memory cell regions includes a semiconductor layer extending in a first direction and a pillar having a side surface in contact with the semiconductor layer and extending in a second direction. A first conductor includes a first portion extending in the first direction and a plurality of second portions extending in a third direction and connected to the first portion. One of the second portions is in contact with the semiconductor layer. Each of a plurality of contact regions includes a plurality of contacts extending in the second direction. A plurality of groups is arranged in the first direction when viewed in the second direction, each of the groups including one of the plurality of memory cell regions, one of the plurality of second portions, and one of the plurality of contact regions, which are arranged in the first direction when viewed in the second direction.

### CROSS-REFERENCE TO RELATED APPLICATION(S)

This application is based upon and claims the benefit of priority from Japanese Patent Application No. 2023-046743, filed Mar. 23, 2023, the entire contents of which are incorporated herein by reference.

### FIELD

Embodiments described herein relate generally to a storage device.

### BACKGROUND

A storage device provided with memory cells arranged in three-dimension is known. In order to increase the integration degree of the storage device, the elements of the storage device are required to be smaller and to be arranged at a higher density. As a consequence, the parasitic capacitance formed between the wiring and the wiring becomes large.

### DESCRIPTION OF THE DRAWINGS

FIG. 1 shows an example of elements and connection of the elements of a storage device of a first embodiment.

FIG. 2 shows elements and connection of the elements of one block of memory cells in the storage device of the first embodiment.

FIG. 3 shows an example of elements and connection of the elements of a sense amplifier unit of the storage device of the first embodiment.

FIG. 4 schematically shows a basic structure of the storage device of the first embodiment.

FIGS. 5-9 shows a layout of different regions of the storage device of the first embodiment.

FIG. 10 shows an example of a structure of a cross section of an electrode pillar of the storage device of the first embodiment.

FIGS. 11-13 shows a layout of different regions of the storage device of the first embodiment.

FIG. 14 shows a cross-sectional structure of a part of the storage device of the first embodiment.

FIG. 15 shows a cross-sectional structure of another part of the storage device of the first embodiment.

FIG. 16 shows a structure of a region of the storage device of the first embodiment.

FIGS. 17A and 17B show a layout of a region of the storage device according to a comparative example.

FIG. 18 shows a layout of a region of a storage device of a modification example of the first embodiment.

### DETAILED DESCRIPTION

Embodiments provide a storage device that enables wiring to be arranged at a larger interval.

In general, according to one embodiment, the storage device is provided with a plurality of memory cell regions, a first conductor, and a plurality of contact regions. Each of the plurality of memory cell regions is provided with a semiconductor layer and a pillar. The semiconductor layer extends in a first direction. The pillar has a side surface in contact with the semiconductor layer and extends in a second direction. The first conductor is provided with a first portion and a plurality of second portions, one of which is in contact with the semiconductor layer. The first portion extends in the first direction. The plurality of second portions extend in a third direction and are connected to the first portion. Each of the plurality of contact regions is provided with a plurality of contacts extending in the second direction. A plurality of groups is arranged in the first direction when viewed in the second direction, each of groups including one of the plurality of memory cell regions, one of the plurality of second portions, and one of the plurality of contact regions, which are arranged in the first direction when viewed in the second direction.

Embodiments are described below with reference to the drawings. In order to distinguish a plurality of elements having substantially the same function and configuration in a certain embodiment or modification example, additional numbers or letters may be added to the end of reference labels.

The drawings are schematic, and a relationship between thickness and plane dimensions, a ratio of a thickness of each layer, or the like may differ from actual ones. In addition, there may be portions where a relationship and a ratio of dimensions of the drawings may differ between figures.

In the present specification and what is claimed, the expression that a certain first element is “connected to” another second element means that the first element is connected to the second element directly or via an element that is constantly or selectively conductive.

Hereinafter, embodiments are described using an xyz orthogonal coordinate system. The positive direction of the vertical axis in the drawings may be referred to as the upper side, and the negative direction may be referred to as the lower side. The positive direction of the horizontal axis in the drawings may be referred to as the right side, and the negative direction may be referred to as the left side. That is, in a plan view (xy-plane view) showing an xy-plane viewed from the +z direction, the upper side indicates the +y direction, and the lower side indicates the −y direction. In the xy-plane view when viewed from the +z direction, the right side indicates the +x direction, and the left side indicates the −x direction. In the xz-plane view when viewed from the −y direction, the upper side indicates the +z direction, and the lower side indicates the −z direction. In the xz-plane view when viewed from the −y direction, the right side indicates the +x direction, and the left side indicates the −x direction.

### 1. First Embodiment

### 1.1. Configuration (Structure)

### 1.1.1. Storage Device

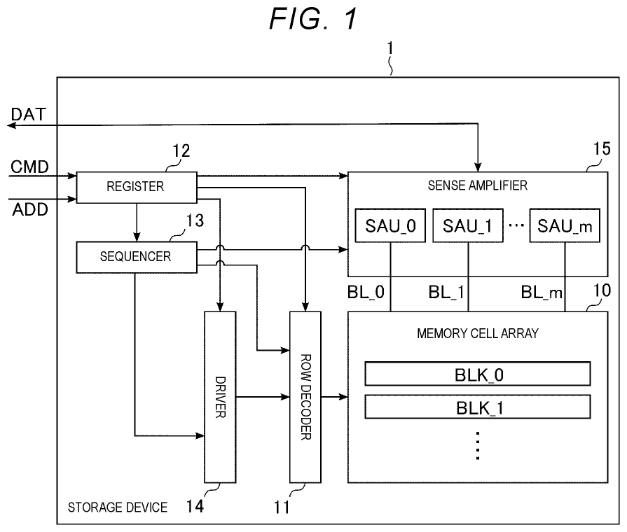

FIG. 1 shows an example of elements and connection of the elements of a storage device of a first embodiment. The storage device 1 is a device that stores data using a memory cell. The storage device 1 is controlled by an external memory controller. In an example, the storage device 1 operates based on the command CMD and the address information ADD received from the memory controller. The storage device 1 receives the data DAT to be written and also outputs the data stored in the storage device 1.

As shown in FIG. 1, the storage device 1 is provided with elements such as a memory cell array 10, a row decoder 11, a register 12, a sequencer 13, a driver 14, and a sense amplifier 15.

The memory cell array 10 includes a group of memory cell transistors and elements connected to the memory cell transistors. The memory cell array 10 is provided with a plurality of memory blocks (blocks) BLK (BLK_0, BLK_1, . . . ). Each block BLK is provided with a plurality of memory cell transistors MT (not shown). In the memory cell array 10, wirings such as a word line WL (not shown) and m+1 bit lines BL (BL_0, BL_1, . . . , BL_m, where m is a positive integer) are also located, and wirings connected to the memory cell transistor MT are also located.

The row decoder 11 is a circuit for selecting the block BLK. The row decoder 11 transfers the voltage supplied from the driver 14 to one selected block BLK based on the block address received from the register 12.

The register 12 is a circuit that stores the command CMD and the address information ADD received by the storage device 1. The command CMD instructs the sequencer 13 to perform various operations including data reading, data writing, and data erasing. The address information ADD designates an access target in the memory cell array 10.

The sequencer 13 is a circuit that controls the operation of the entire storage device 1. The sequencer 13 controls the row decoder 11, the driver 14, and the sense amplifier 15 based on the command CMD received from the register 12 to execute various operations including data reading, data writing, and data erasing.

The driver 14 is a circuit that generates a plurality of voltages having different magnitudes and applies the generated voltages to elements of the storage device 1. The driver 14 supplies the voltages selected among the plurality of generated voltages based on the control of the sequencer 13 and the address information ADD to the row decoder 11.

The sense amplifier 15 is a circuit that outputs a signal based on data stored in the memory cell array 10. The sense amplifier 15 is provided with (m+1) sense amplifier units SAU (SAU_0, SAU_1, . . . , SAU_m) having the same number as the number of bit lines BL. Each sense amplifier unit SAU is connected to one bit line BL. During data reading, each sense amplifier unit SAU senses the state of the memory cell transistor MT connected via the bit line BL connected to the sense amplifier unit SAU, and generates read data based on the sensed state. In addition, each sense amplifier unit SAU controls a voltage of the bit line BL connected to the sense amplifier unit SAU during data writing to the memory cell transistor MT connected to the bit line BL.

### 1.1.2 Memory Cell Array

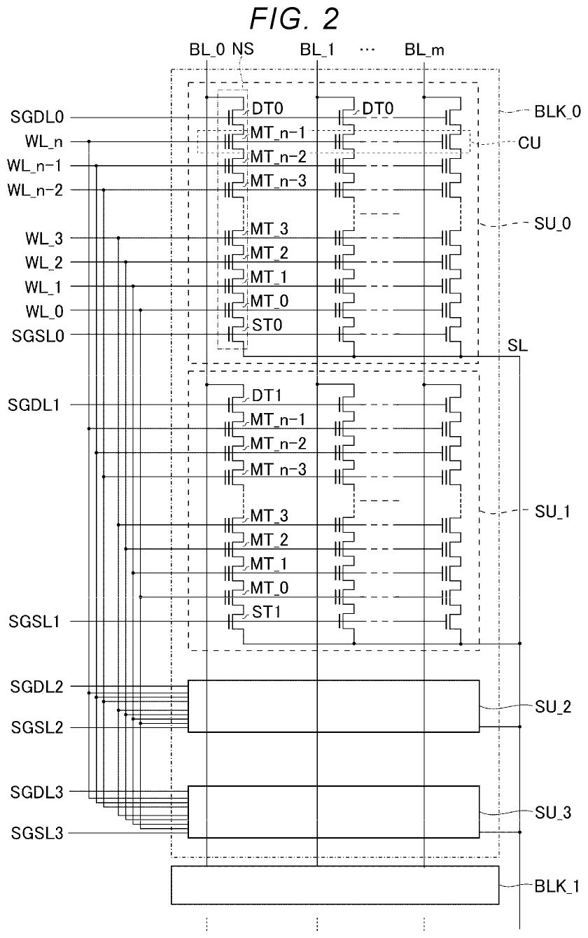

FIG. 2 shows elements and connection of the elements of one block BLK of the storage device of the first embodiment. Each of the plurality of blocks BLK, for example, all of the blocks BLK, is provided with the elements and the connection shown in FIG. 2.

One block BLK is provided with a plurality of string units SU. FIG. 2 shows an example of four string units SU_0 to SU_3.

As shown in FIG. 2, each of the m+1 bit lines BL_0 to BL_m is connected to one NAND string NS from each of the string units SU_0 to SU_3 in each block BLK.

Each NAND string NS is provided with one select gate transistor ST (ST0, ST1, ST2, or ST3), n+1 memory cell transistors MT, where n is a positive integer, and one select gate transistor DT (DT0, DT1, DT2, or DT3). In FIG. 2, the select gate transistors DT2, DT3, ST2, and ST3 are not shown. The memory cell transistor MT is an element provided with a control gate electrode and a charge storage film insulated from the surroundings, and stores data in a non-volatile manner based on an amount of charge in the charge storage film. In each of the NAND strings NS, one select gate transistor ST, n+1 memory cell transistors MT, and one select gate transistor DT are connected in series between the source line SL and one bit line BL in this order.

A plurality of NAND strings NS connected to a plurality of different bit lines BL respectively constitute one string unit SU. In each string unit SU, the control gate electrodes of the memory cell transistors MT_0 to MT_n−1 are connected to the word lines WL_0 to WL_n−1, respectively. A group of memory cell transistors MT sharing the word line WL in one string unit SU is referred to as a cell unit CU.

The select gate transistors DT0 to DT3 belong to the string units SU_0 to SU_3, respectively. The gate of each select gate transistor DT0 in the plurality of NAND strings NS of the string unit SU_0 is connected to a select gate line SGDL0. Similarly, the gates of each of select gate transistors DT1, DT2, and DT3 in the plurality of NAND strings NS of the string units SU_1, SU_2, and SU_3 are connected to the select gate lines SGDL1, SGDL2, and SGDL3.

The select gate transistors ST0 to ST4 belong to the string units SU_0 to SU_3, respectively. The gate of each select gate transistor ST0 in the plurality of NAND strings NS of the string unit SU_0 is connected to a select gate line SGSL0. Similarly, the gates of each of select gate transistors ST1, ST2, and ST3 in the plurality of NAND strings NS of each of the string units SU_1, SU_2, and SU_3 are connected to the select gate lines SGSL1, SGSL2, and SGSDL3.

### 1.1.3. Sense Amplifier Unit

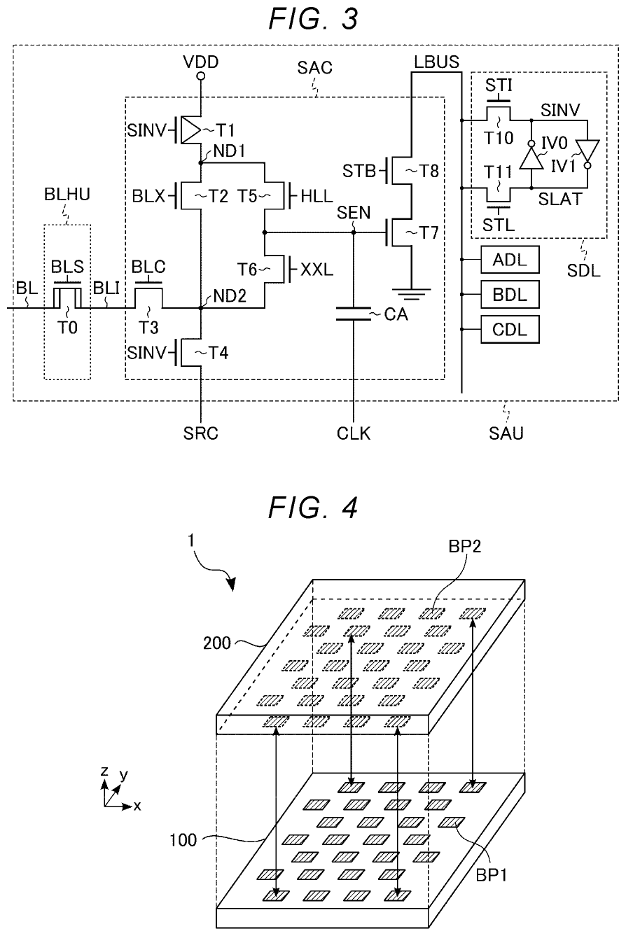

FIG. 3 shows an example of elements and connection of the elements of a sense amplifier unit of the storage device of the first embodiment. As shown in FIG. 3, the sense amplifier unit SAU is provided with a sense amplifier circuit SAC, a bit line connection unit BLHU, a bus LBUS, and a plurality of latch circuits, for example, latch circuits SDL, ADL, BDL, and CDL. Hereinafter, one of the source and the drain of the transistor may be referred to as one end, and the other of the source and the drain may be referred to as the other end.

The bit line connection unit BLHU is a switch circuit for preventing application of a high voltage, which is applied to the channel of the NAND string NS during the data erasing, to the sense amplifier circuit SAC. The bit line connection unit BLHU is provided with a transistor TO. In an example, the transistor T0 is a p-type metal oxide semiconductor field effect transistor (MOSFET). One end of the transistor T0 is connected to one bit line BL. The other end of the transistor T0 is connected to the sense amplifier circuit SAC via a wiring BLI.

The sense amplifier circuit SAC is a circuit that determines the value of data read based on the voltage of the bit line BL to which the sense amplifier circuit SAC is connected during data reading, and applies the voltage based on the data to be written to the bit line BL during data writing. In a case where the control signal STB is asserted during data reading, the sense amplifier circuit SAC outputs the data determined to be stored in the memory cell transistor MT connected to the bit line BL based on the voltage of the bit line BL to which the sense amplifier circuit SAC is connected.

The sense amplifier circuit SAC is provided with transistors T1 to T8, a capacitor CA, a wiring BL1, and nodes ND1, ND2, SEN, and SRC. In an example, the transistor T1 is a p-type MOSFET, and the transistors T2 to T7 are n-type MOSFETs.

The transistor T1 is connected between a node that receives the power source voltage VDD and the node ND1. The gate of the transistor T1 is connected to the node SINV.

The transistor T2 is connected between the node ND1 and the node ND2. The gate of the transistor T2 receives the control signal BLX. In an example, the control signal BLX is supplied from the sequencer 13.

The transistor T3 is connected between the wiring BLI and the node ND2. The gate of the transistor T3 receives the control signal BLC. In an example, the control signal BLC is supplied from the sequencer 13.

The transistor T4 is connected between the node ND2 and the node SRC. In an example, the node SRC receives the ground voltage VSS. The gate of the transistor T4 is connected to the node SINV.

The transistor T5 is connected between the node ND1 and the node SEN. The gate of the transistor T5 receives the control signal HLL. In an example, the control signal HLL is supplied from the sequencer 13.

The transistor T6 is connected between the node SEN and the node ND2. The gate of the transistor T6 receives the control signal XXL. In an example, the control signal XXL is supplied from the sequencer 13.

The capacitor CA is connected to the node SEN in one electrode. The capacitor receives the control signal CLK in the other electrode. In an example, the control signal CLK is supplied from the sequencer 13.

One end of the transistor T7 is connected to a node that receives the ground voltage VSS. A gate of transistor T7 is connected to the node SEN.

The transistor T8 is connected between the other end of the transistor T7 and the bus LBUS. The gate of the transistor T8 receives the control signal STB. In an example, the control signal STB is supplied from the sequencer 13.

Each of the latch circuits SDL, ADL, BDL, and CDL is a circuit capable of temporarily storing data. The latch circuit SDL is provided with the inverter circuits IV0 and IV1, the transistors T10 and T11, and the nodes SINV and SLAT. In an example, the transistors T10 and T11 are n-type MOSFETs. The latch circuit SDL stores the data in the node SLAT.

The inverter circuit IV0 is connected to the node SLAT at the input and is connected to the node SINV at the output. The inverter circuit IV1 is connected to the node SINV at the input and is connected to the node SLAT at the output.

The transistor T10 is connected between the bus LBUS and the node SINV. The gate of the transistor T10 receives the control signal ST1. In an example, the control signal ST1 is supplied from the sequencer 13.

The transistor T11 is connected between the bus LBUS and the node SLAT. The gate of the transistor T11 receives the control signal STL. In an example, the control signal STL is supplied from the sequencer 13.

### 1.1.4. Basic Structure of Storage Device

FIG. 4 schematically shows a basic structure of the storage device of the first embodiment. As shown in FIG. 4, the storage device 1 is provided with a first structure 100 and a second structure 200 arranged along the z-axis. The second structure 200 is located in the +2 direction with respect to the first structure 100. The first structure 100 and the second structure 200 extend along a plane including an x-axis and a y-axis (that is, the xy-plane). The first structure 100 and the second structure 200 are separately manufactured and then bonded to each other. Specifically, a structure inverted with respect to the xy-plane of the second structure 200 is formed, the formed structure is inverted with respect to the xy-plane, and the first structure 100 and the second structure 200 are joined to each other. FIG. 4 shows a state before the bonding for facilitating understanding.

The first structure 100 is provided with a plurality of conductive bonding pads BP1. The second structure 200 is provided with a plurality of conductive bonding pads BP2. Each bonding pad BP1 of the first structure 100 faces one bonding pad BP2 of the second structure 200. As a result of the bonding of the first structure 100 and the second structure 200, each bonding pad BP1 of the first structure is in contact with one bonding pad BP2 of the second structure 200.

In an example, the first structure 100 is a chip provided with a structure that functions as an element of the memory cell array 10. In an example, the second structure 200 is a chip provided with a structure that functions as an element of the row decoder 11, the register 12, the sequencer 13, the driver 14, and the sense amplifier 15.

### 1.1.5. Structure of Storage Device

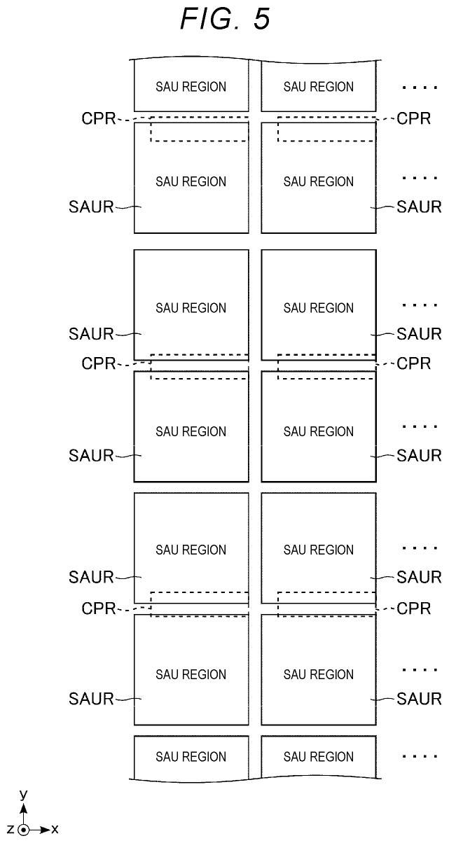

FIG. 5 shows a layout of a part of the storage device of the first embodiment along an xy-plane. As will be described later, the storage device 1 is provided with a plurality of layers arranged along the z-axis. FIG. 5 shows a structure in a certain layer of the storage device 1 and shows a structure in the first structure 100.

As shown in FIG. 5, the storage device 1 is provided with a plurality of sense amplifier unit regions (or SAU regions) SAUR. Each SAU region SAUR is provided with one sense amplifier unit SAU, that is, is provided with the element of one sense amplifier unit SAU.

The SAU region SAUR has a quadrangular shape in an example. FIG. 5 shows this example. The SAU region SAUR is arranged along the xy-plane. The adjacent SAU regions SAUR have an interval, and for example, an insulator is provided between the adjacent SAU regions SAUR. In an example, the SAU region SAUR is arranged in a matrix shape as shown in FIG. 5 and is arranged along the x-axis and the y-axis. Alternatively, the SAU region SAUR may be arranged along only one of the x-axis and the y-axis.

The storage device 1 is provided with a plurality of contact regions (or, CC regions) CPR. The CC region CPR is located in the first structure 100, extends along the x-axis, and is provided with a plurality of contacts CP. The structure of the CC region CPR will be described in detail later. The CC region CPR overlaps with the SAU region SAUR. In an example, the dimension of each CC region CPR along the x-axis is smaller than the dimension of the SAU region SAUR along the x-axis. In an example, each CC region CPR is located between the left end and the right end of the SAU region SAUR arranged along the y-axis. On the other hand, the relative positional relationship on the y-axis between the CC region CPR and the SAU region SAUR is not limited to any form. FIG. 5 shows an example in which some CC regions CPR overlap with two SAU regions SAUR arranged along the y-axis. FIG. 5 shows an example in which some of the CC regions CPR overlap with the edge of one SAU region SAUR.

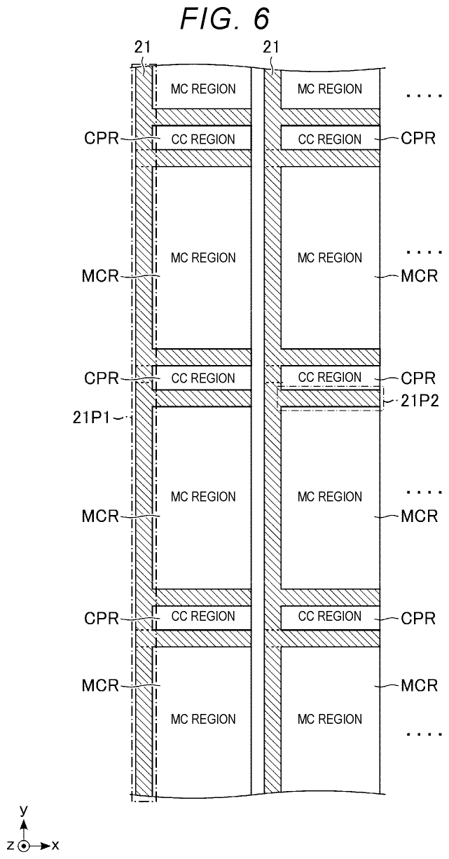

FIG. 6 shows a layout of a part of the storage device of the first embodiment along an xy-plane. FIG. 6 shows a layer located in the −z direction with respect to the region shown in FIG. 5. FIG. 6 shows the structure in the first structure 100. As shown in FIG. 6, the storage device 1 is provided with a plurality of memory cell regions (or MC regions) MCR, a plurality of CC regions, and a plurality of conductors 21.

The MC region MCR is a region in which the memory cell transistor MT and a structure related to the memory cell transistor MT are provided. The plurality of MC regions MCR are arranged at intervals along the y-axis to form a column. The plurality of columns of the MC region MCR are arranged at intervals along the x-axis.

The conductor 21 connects the conductors in the plurality of MC regions MCR to each other. Each conductor 21 is provided with one first portion 21P1 and a plurality of second portions 21P2. The first portion 21P1 extends along the y-axis. The first portion 21P1 is arranged in one column of the MC region MCR. The first portion 21P1 is adjacent to one of the two edges arranged along the x-axis in one column of the MC region MCR. FIG. 6 shows an example in which the first portion 21P1 is located on the left side of the column of the MC region MCR.

The second portions 21P2 extend along the x-axis and are arranged at intervals along the y-axis. Each second portion 21P2 is located between the two MC regions MCR arranged along the y-axis. One second portion 21P2 or two or more second portions 21P2 having an interval are located between the two MC regions MCR arranged along the y-axis. FIG. 11 shows an example in which two second portions 21P2 are located. Each second portion 21P2 is connected to the first portion 21P1 on one of the two sides arranged along the x-axis of the second portion 21P2. FIG. 6 shows an example in which each second portion 21P2 is connected to the first portion 21P1 at the left end of the second portion 21P2. In an example, the right end of the second portion 21P2 overlaps with the right end of the MC region MCR or is located in the vicinity of the right end of the MC region MCR.

The CC region CPR extends along the x-axis and is arranged at intervals along the y-axis. Each CC region CPR is located between two MC regions MCR arranged along the y-axis. In an example, each CC region CPR is located between the two second portions 21P2 arranged along the y-axis. In an example, the right end of the CC region CPR overlaps with the right end of the MC region MCR or is located in the vicinity of the right end of the MC region MCR.

Based on the above layout, the MC region MCR, the second portion 21P2, and the CC region CPR are disposed along the y-axis. That is, one MC region MCR, one or more second portions 21P2, and one CC region CPR are continuously arranged in this order along the y-axis. The MC region MCR, the second portion 21P2, and the CC region CPR arranged along the y-axis form a group, and such groups are repeatedly provided along the y-axis.

In addition, based on the above layout, in an example, the group of the column of each MC region MCR, the CC region CPR located in the column of the MC region MCR, and the conductors 21 arranged with the MC region MCR overlaps with the SAU region SAUR.

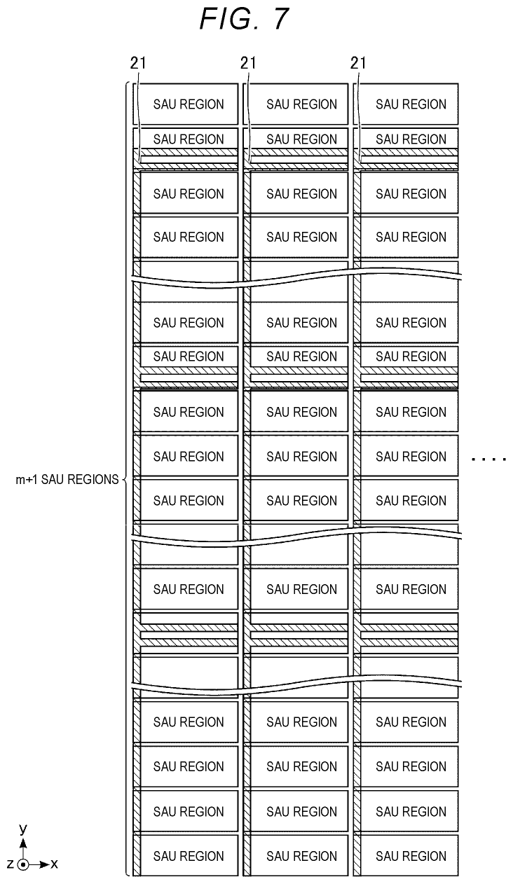

FIG. 7 shows a layout of a part of the storage device of the first embodiment along an xy-plane. Specifically, FIG. 7 shows a relative positional relationship between the conductor 21 and the SAU region SAUR.

As shown in FIG. 7, a plurality of SAU regions SAUR are arranged along the y-axis between each two conductors 21 arranged along the x-axis. The same number of SAU regions SAUR as the number of bit lines BL, that is, m+1 SAU regions SAUR are located between the imaginary straight line including the upper end of each conductor 21 and the imaginary straight line including the lower end of each conductor 21.

In an example, one conductor 21 is provided in a single y-axis direction. That is, another conductor 21 is not located in the +y direction of each conductor 21, and another conductor 21 is not located in the −y direction of each conductor 21.

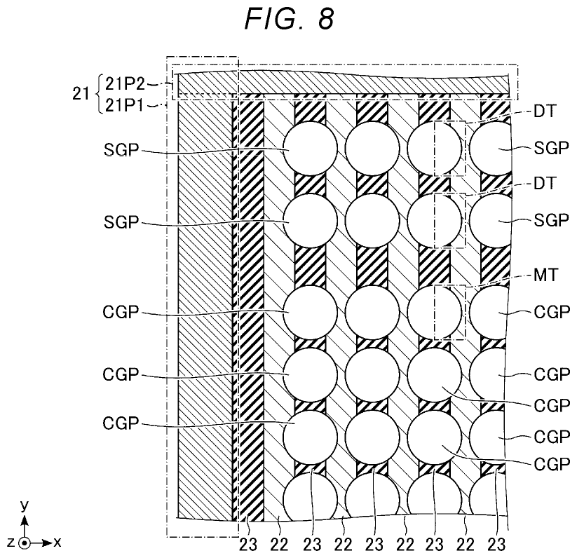

FIG. 8 shows a layout of a part of the storage device of the first embodiment along an xy-plane. FIG. 8 shows the layout of the MC region MCR shown in FIG. 6, and shows an enlarged part of FIG. 6. FIG. 8 shows one of the plurality of layers arranged along the z-axis. As shown in FIG. 8, each MC region MCR is provided with a conductor 21, a plurality of semiconductors 22, a plurality of insulators 23, and a plurality of electrode pillars CGP and SGP in one layer.

In an example, the semiconductor 22 is silicon. The semiconductor 22 contains an impurity. The impurity includes an element that imparts n-type or p-type conductivity to the semiconductor 22, and in an example, includes boron or arsenic. The semiconductors 22 extend along the y-axis and are arranged at intervals along the x-axis. The semiconductor 22 is in contact with the second portion 21P2 of the conductor 21 on the side in the +y direction. One of the semiconductors 22 arranged along the x-axis that is located at the end has an interval with the conductor 21.

Each insulator 23 occupies a region between the semiconductors 22 or a region between the first portion 21P1 of the conductor 21 and the semiconductors 22.

A plurality of groups each including one conductor 21, a plurality of semiconductors 22, and one insulator 23 shown in FIG. 8, is provided in each of the plurality of layers. That is, the structure of one conductor 21, a plurality of semiconductors 22, and one insulator 23 shown in FIG. 8 is repeatedly provided along the z-axis.

Each electrode pillar SGP is provided with an insulator, a conductor, and a semiconductor. Each electrode pillar SGP has a columnar shape and extends along the z-axis. The electrode pillar SGP overlaps with one insulator 23. Each electrode pillar SGP partially overlaps with the two semiconductors 22 and the insulator 23 between the two semiconductors 22, and is in contact with the two semiconductors 22 on the side surface. Specifically, each electrode pillar SGP is in contact with the semiconductor 22 on the surface on the −x direction side and the surface on the +x direction side. In an example, the electrode pillars SGP are arranged along the x-axis, and the groups of the electrode pillars SGP arranged along the x-axis, are arranged along the y-axis. A portion of each electrode pillar SGP and a portion of the semiconductor 22 that is in contact with the electrode pillar SGP function as one select gate transistor DT.

Each electrode pillar CGP is provided with an insulator, a conductor, and a semiconductor. The electrode pillar CGP has a columnar shape and extends along the z-axis. The electrode pillar CGP overlaps with one insulator 23. Each electrode pillar CGP partially overlaps with the two semiconductors 22 and the insulator 23 between the two semiconductors 22, and is in contact with the two semiconductors 22 on the side surface. Specifically, each electrode pillar CGP is in contact with the semiconductor 22 on the surface on the −x direction side and the surface on the +x direction side. In an example, the electrode pillars CGP are arranged in a matrix shape along the x-axis and the y-axis. FIG. 8 shows this example. In another example, the electrode pillars CGP may be arranged in a zigzag shape on the xy-plane. A portion of each electrode pillar CGP and a portion of the semiconductor 22 that is in contact with the electrode pillar SGP function as one memory cell transistor MT.

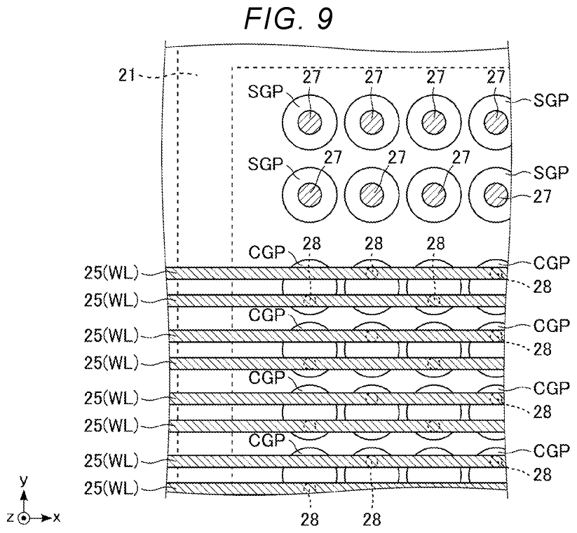

FIG. 9 shows a layout of a part of the storage device of the first embodiment along an xy-plane. FIG. 9 shows a layer located in the +z direction with respect to the electrode pillars SGP and CGP, and shows the same region as the region shown in FIG. 8.

As shown in FIG. 9, the storage device 1 is provided with a plurality of conductors 25 and a plurality of contacts 27 and 28. Each contact 27 overlaps with one electrode pillar SGP. In an example, each contact 27 has a columnar shape and extends along the z-axis. Each contact 27 is located in the +z direction with respect to the electrode pillar SGP.

Each contact 28 overlaps with one electrode pillar CGP. In an example, each contact 28 has a columnar shape and extends along the z-axis. Each contact 28 is located in the +z direction with respect to the electrode pillar CGP.

The conductors 25 extend along the x-axis and are arranged at intervals along the y-axis. Each conductor 25 functions as one word line WL. Each conductor 25 overlaps with a plurality of contacts 28 that are arranged along the x-axis and overlap with a plurality of electrode pillars CGP. Each conductor 25 is located in the +z direction with respect to the contact 28. In an example, the two conductors 25 overlap each other in a single group of a plurality of electrode pillars CGP arranged along the x-axis. Each of the two conductors 25 is connected to every other electrode pillars CGP in the group, via the contacts 28.

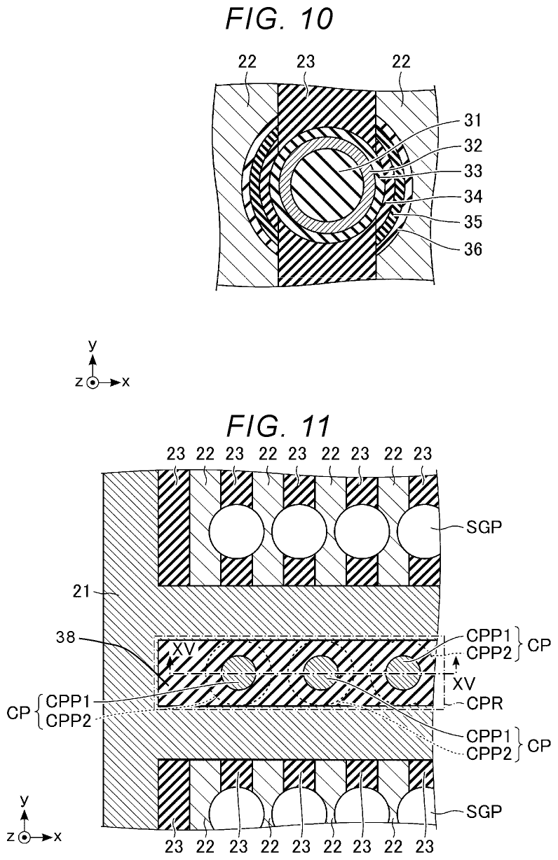

FIG. 10 shows an example of a structure of a cross section of an electrode pillar of the storage device of the first embodiment. As shown in FIG. 10, the electrode pillar CGP is provided with an insulator 31, a conductor 32, a block insulator 33, a block insulator 34, a charge storage film 35, and a tunnel insulator 36 in an example.

The insulator 31 has a columnar shape extending along the z-axis. The conductor 32 surrounds the side surface of the insulator 31. In an example, the conductor 32 is provided with a semiconductor containing metal or an impurity, or is configured with a semiconductor containing a metal or an impurity. Examples of the metal include tungsten (W) and titanium nitride (TiN). Examples of the semiconductor include silicon. Examples of the impurities include elements that impart n-type or p-type conductivity to the semiconductor.

Block insulator 33 surround the side surfaces of the conductors 32. In an example, the block insulator 33 contains an oxide or nitride of aluminum (Al), hafnium (Hf), Ti, zirconium (Zr), and lanthanum (La), or contains silicon oxide or silicon oxynitride (SiON), or is formed of these materials. The block insulator 33 is in contact with two portions of the side surface of the insulator 23 that face each other along the x-axis, that is, a portion on the +y-direction side and a portion on the −y-direction side.

Each block insulator 34 surrounds at least a part of the side surface of the block insulator 33 and is located between the block insulator 33 and one semiconductor 22. In an example, each block insulator 34 is in contact with two portions of the side surface of the block insulator 33 that is, a portion on the +x direction side and a portion on the −x direction side. In an example, the block insulator 34 contains silicon oxide or is formed of silicon oxide.

In an example in which the charge storage film 35 surrounds the side surface of the block insulator 34 and is located between the block insulator 34 and one semiconductor 22, the charge storage film 35 stores charges. The charge storage film 35 contains silicon nitride or is formed of silicon nitride in an example.

The tunnel insulator 36 surrounds the side surfaces of the charge storage film 35 and is located between the charge storage film 35 and one semiconductor 22. The tunnel insulator 36 is in contact with one semiconductor 22. In an example, the tunnel insulator 36 contains silicon oxide or is formed of silicon oxide.

The electrode pillar SGP has the same structure as the electrode pillar CGP.

FIG. 11 shows a layout of a part of the storage device of the first embodiment along an xy-plane. FIG. 11 shows the same layer as the layer in which the structure shown in FIG. 8 is located, and shows the CC region CPR and the region around the CC region CPR. As shown in FIG. 11 and as described above with reference to FIG. 5, the storage device 1 is provided with a plurality of contacts CP in the CC region CPR. Each contact CP is provided with a first portion CPP1 and a second portion CPP2. In each contact CP, the first portion CPP1 and the second portion CPP2 overlap each other. The second portion CPP2 has an area larger than the area of the first portion CPP1 in the xy-plane. The first portion CPP1 has a columnar shape extending along the y-axis and is connected to the second portion CPP2. A plurality of second portions CPP2 are located in different layers, as will be described in detail later. The side surface of each second portion CPP2 is in contact with the side surface of the second portion 21P2 of the conductor 21 in the layer in which the second portion CPP2 is located.

An insulator 38 is provided in a region in the CC region CPR where the contact CP is not provided. In an example, the insulator 38 contains silicon oxide or is formed of silicon oxide.

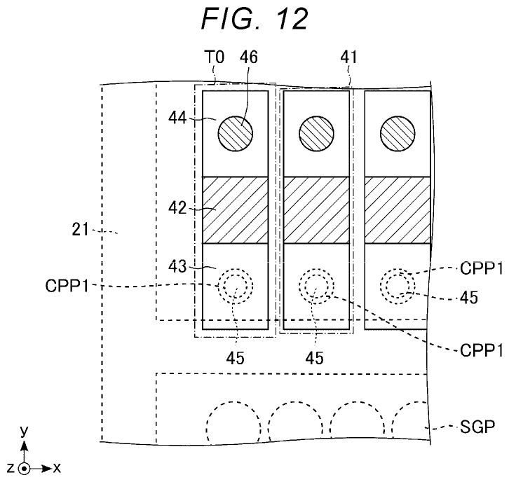

FIG. 12 shows a layout of a part of the storage device of the first embodiment along an xy-plane. FIG. 12 shows a layer located in the +z direction with respect to the layer in which the structure shown in FIG. 11 is located, and shows the same region as the region shown in FIG. 10 for the region on the xy-plane.

As shown in FIG. 12, the storage device 1 is provided with a transistor T0. The transistor T0 is located in the +z direction with respect to the first portion CPP1 of the contact CP. The transistor T0 is provided with a semiconductor 41, a gate electrode 42, and source/drain regions 43 and 44. In an example, the semiconductor 41 contains silicon or is formed of silicon. In an example, the semiconductor 41 extends along the y-axis. The semiconductor 41 overlaps with one first portion CPP1.

The source/drain regions 43 and 44 are formed in the semiconductor 41. In an example, the source/drain regions 43 and 44 are arranged along the y-axis. The source/drain region 43 overlaps with one first portion CPP1 and overlaps with the contact 45. The contact 45 is provided with a conductor or is configured with a conductor. The contact 45 has a columnar shape extending along the z-axis. The contact 45 is in contact with the source/drain region 43 and the contact 45.

The gate electrode 42 is located between the two source/drain regions 43. The gate electrode 42 is located in the +z direction with respect to the semiconductor 41. A gate insulator is provided between the gate electrode 42 and the semiconductor 41.

The source/drain region 44 overlaps with the contact 46. The contact 46 is provided with a conductor or is configured with a conductor. The contact 46 has a columnar shape extending along the z-axis. The contact 46 is in contact with the source/drain region 44.

The transistor T0 is useful for selectively electrically connecting one of the plurality of contacts 46 to which the transistor T0 is connected and one of the plurality of contacts 45 to which the transistor T0 is connected. Therefore, by providing the transistor T0 and turning on the selected one transistor T0, the capacitance of the conductor (wiring) connected to the transistor T0 is reduced, and the signal can be transmitted at high speed through the wiring. However, the transistor T0 need not be necessarily provided.

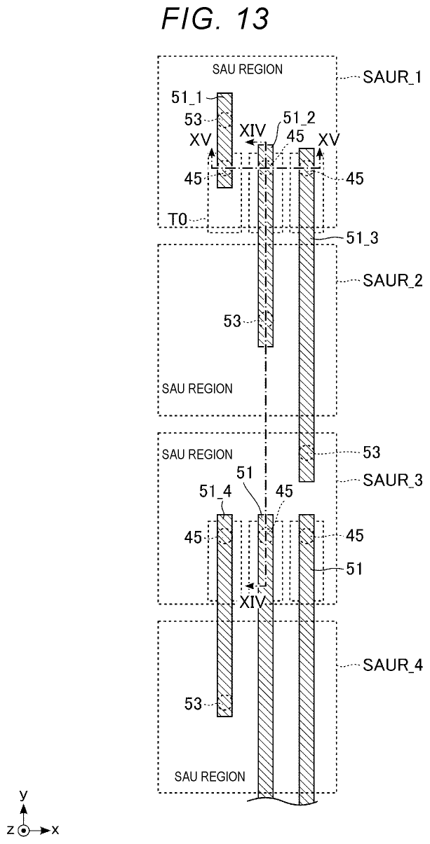

FIG. 13 shows a layout of a part of the storage device of the first embodiment along an xy-plane. FIG. 13 shows a layer that is located in the +z direction with respect to the layer in which the structure shown in FIG. 12 is located, and is located in the −z direction with respect to the layer in which the structure shown in FIG. 5 is located. The structure of FIG. 13 is located in the first structure 100.

As shown in FIG. 13, the storage device 1 is provided with a plurality of conductors 51. Each conductor 51 functions as a part of one wiring BLI. The conductor 51 extends along the y-axis. Each conductor 51 overlaps with one contact 45 in a portion provided with one end. Each of the conductors 51 overlaps with one SAU region SAUR in a portion provided with the other end.

One contact 53 is provided on the upper surface of each conductor 51. Each contact 53 is connected to the sense amplifier unit SAU in one SAU region SAUR via a conductor (not shown). The sense amplifier unit SAU in one SAU region SAUR is connected to only one conductor 51 via the contact 53.

Each conductor 51 is connected to one SAU region SAUR. In an example, each conductor 51 is connected to an SAU region SAUR that is not overlapped with an SAU region SAUR to which another conductor 51 is connected and that has the shortest length of the conductor 51. In the example of FIG. 13, the conductor 51_1 is connected to the sense amplifier unit SAU in the SAU region SAUR_1. The conductor 51_2 is connected to the sense amplifier unit SAU in the SAU region SAUR_2. The conductor 51_3 is connected to the sense amplifier unit SAU in the SAU region SAUR_3. The conductor 51_4 is connected to the sense amplifier unit SAU in the SAU region SAUR_4.

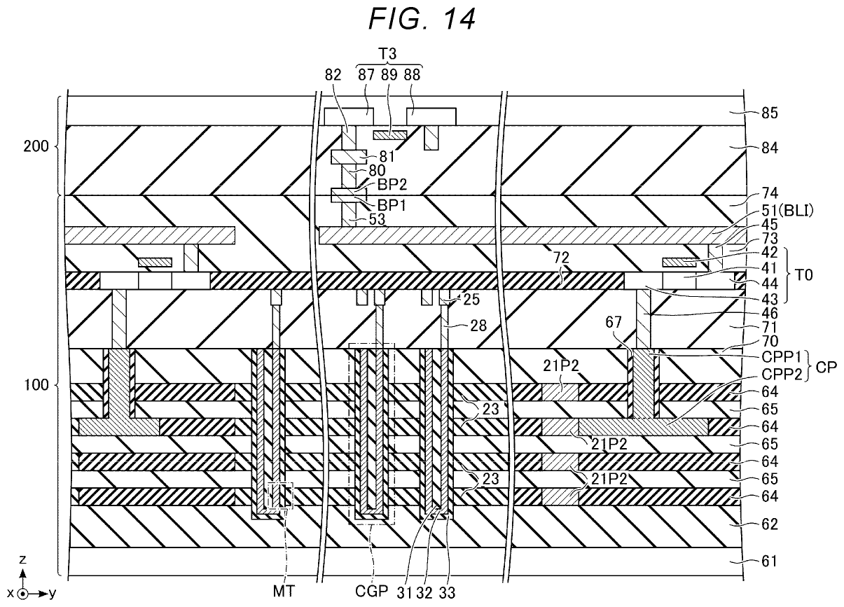

FIG. 14 shows a structure along the yz-plane of a part of the storage device of the first embodiment, and shows a structure along the line XIV-XIV of FIG. 13. The yz-plane is a plane including the y-axis and the z-axis.

As shown in FIG. 14, the first structure 100 is further provided with a semiconductor 61, and insulators 62, 64, 65, 67, 70, 71, 72, 73, and 74.

In an example, the semiconductor 61 contains silicon or is formed of silicon.

The insulator 62 is located on the upper surface of the semiconductor 61. In an example, the insulator 62 contains silicon oxide or is formed of silicon oxide.

The insulators 64 and 65 are alternately located on the upper surface of the semiconductor 61. The number of groups of the insulators 64 and 65 is equal to the number of the bit lines BL, that is, m+1. FIG. 14 shows only four groups of insulators 64 and 65. In an example, the insulators 64 and 65 contain silicon nitride, silicon oxide, or silicon oxide containing nitrogen, or are formed of silicon nitride, silicon oxide, or silicon oxide containing nitrogen.

The insulator 70 is located on the upper surface of the uppermost insulator 64. In an example, the insulator 70 contains silicon oxide or is formed of silicon oxide. The semiconductor 22 and the second portion 21P2 of the conductor 21 are located in the layer of each insulator 64.

The electrode pillar CGP penetrates the insulators 70, 64, and 65 and the semiconductor 22. A lower surface of a part of the electrode pillar CGP is located in the insulator 62. In an example, the respective lower surfaces of the block insulator 33, the conductor 32, and the insulator 31 are located in the insulator 62.

Each contact CP is provided with the second portion CPP2 located in a layer of one insulator 64 and the first portion CPP1 having a lower surface in contact with an upper surface of the second portion CPP2. The first portion CPP1 penetrates one or a plurality of groups of the insulator 70 and the insulators 64 and 65. Each second portion CPP2 is in contact with one second portion 21P2 on the side surface. Each contact CP is in contact with only the second portion 21P2 of the layer in which the lower end of the contact CP is located, among the plurality of second portions 21P2 respectively located in the plurality of layers. Each second portion 21P2 may contain, in a portion provided with the edge on the +y direction side, a material different from that of the rest of the portion. An example of such a material includes a material of the second portion CPP2 of the contact CP.

Each insulator 67 covers a side surface of the first portion CPP1 of one contact CP.

The upper surface of each electrode pillar CGP is in contact with the lower surface of one contact 28. The upper surface of each contact 28 is in contact with the lower surface of one conductor 25.

The upper surface of each contact CP is connected to the lower surface of one contact 46.

The insulator 71 is located in a region in which the contact 28, the conductor 25, and the contact 46 are not provided in the layer in which the contact 28, the conductor 25, and the contact 46 are located. In an example, the insulator 71 contains silicon oxide or is formed of silicon oxide.

The upper surface of each contact 46 is in contact with the lower surface of the source/drain region 43 of one transistor T0. The source/drain regions 43 and 44 are formed in the semiconductor 41. The gate electrode 42 is located above a region of the semiconductor 41 sandwiched between the source/drain regions 43 and 44.

The insulator 72 is located in a region in which the semiconductor 41 is not provided in the layer in which the semiconductor 41 is located. In an example, the insulator 72 contains silicon oxide or is formed of silicon oxide.

An upper surface of the source/drain region 44 is in contact with a lower surface of the contact 45.

The insulator 73 is located in a layer above the layer in which the insulator 72 and the semiconductor 41 are located. The insulator 73 is located in a region in which the gate electrode 42 and the contact 45 are not provided in a region above the insulator 72 and the semiconductor 41. In an example, the insulator 73 contains silicon oxide or is formed of silicon oxide.

The conductor 51 is located on the upper surface of the insulator 73.

Each of the contacts 53 is located on the upper surface of one conductor 51. Each of the bonding pads BP1 is located on the upper surface of one contact 53.

The insulator 74 is located in the layer above the layer of the conductor 51. The insulator 74 is located in a region in which the contact 53 and the bonding pad BP1 are not provided in the region above the conductor 51.

The second structure 200 is further provided with a contact 80, a conductor 81, a contact 82, source/drain regions 87 and 88, a gate electrode 89, a semiconductor 85, and an insulator 84.

Each of the contacts 80 is located on the upper surface of one bonding pad BP2. The contact 80 has a columnar shape, extends along the y-axis, and is provided with a conductor or is configured with a conductor.

Each conductor 81 is located on the upper surface of one contact 80. Each contact 82 is located on the upper surface of one conductor 81.

The semiconductor 85 is located above the insulator 74. In an example, the semiconductor 85 contains silicon or is formed of silicon. The source/drain regions 87 and 88 are located in the semiconductor 85. A lower surface of the source/drain region 87 is in contact with an upper surface of one contact 82. The gate electrode 89 is located below a region between the source/drain region 87 and the source/drain region 88 in the semiconductor 85. The source/drain regions 87 and 88 and the gate electrode 89 are provided in one transistor T3.

The insulator 84 is located in a region where the bonding pad BP2, the contact 80, the conductor 81, the contact 82, and the gate electrode 89 are not provided, in the layers between the layer in which the insulator 74 is located and the layer in which the semiconductor 85 is located.

The insulator 84 and the semiconductor 85 are further provided with elements that configure the transistor, the wiring, and the inverter circuit provided in the sense amplifier unit SAU.

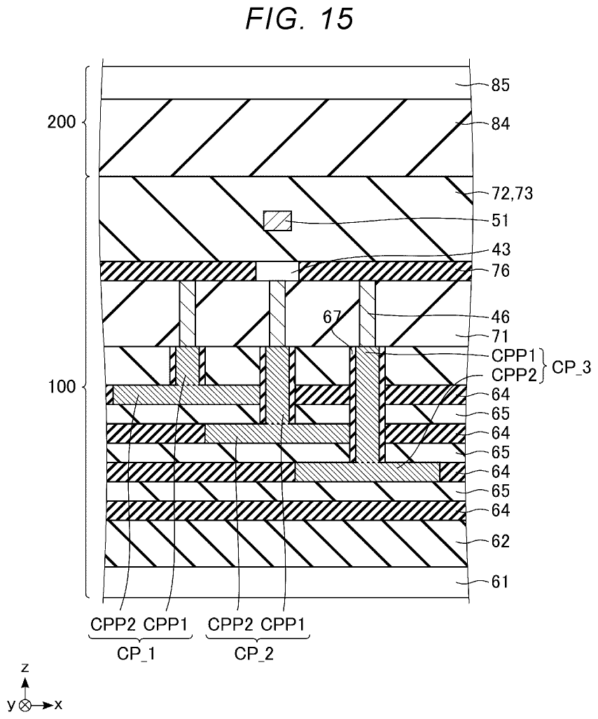

FIG. 15 shows a structure along the xz-plane of a part of the storage device of the first embodiment, and shows a structure along the line XV-XV of FIG. 11. FIG. 15 shows, as an example, three contacts CP_1, CP_2, and CP_3. The contacts CP_1, CP_2, and CP_3 are arranged in the +x direction in this order. The plurality of different contacts CP are located in different layers on the lower surface of each of the plurality of different contacts CP. That is, the respective second portions CPP2 of the plurality of different contacts CP are located in the different layers.

The second portion CPP2 of the contact CP_1 is located on the uppermost layer of the insulator 64, that is, the layer located first in the −z direction. A lower surface of the first portion CPP1 of the contact CP_1 is connected to an upper surface of the second portion CPP2 of the contact CP_1.

The second portion CPP2 of the contact CP_2 is located in the layer of the insulator 64 located second from the top, that is, the layer located second in the −z direction. A lower surface of the first portion CPP1 of the contact CP_2 is connected to an upper surface of the second portion CPP2 of the contact CP_2.

The second portion CPP2 of the contact CP_3 is located in the layer of the insulator 64 located third from the top, that is, the layer located third in the −z direction. A lower surface of the first portion CPP1 of the contact CP_3 is connected to an upper surface of the second portion CPP2 of the contact CP_3.

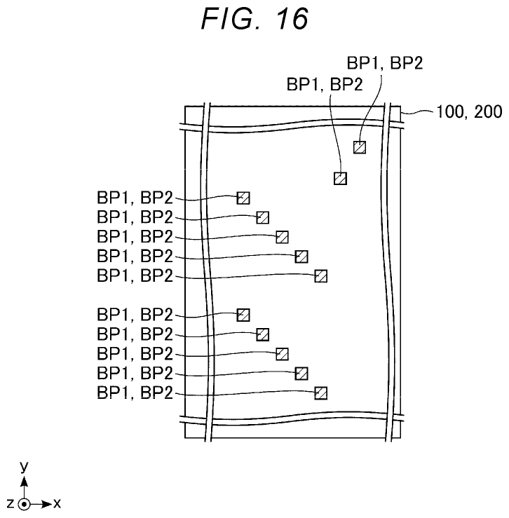

FIG. 16 shows a structure of a part of the storage device of the first embodiment along the xy-plane. As described above with reference to FIG. 14, the bonding pads BP1 and BP2 are located at the location of the contact 53 on the xy-plane. Therefore, as is clear from the description made above with reference to FIGS. 5 to 15, the bonding pads BP1 and BP2 of the first structure 100 and the second structure 200 are distributed over a wide range of the storage device 1. FIG. 16 shows an example of the layout of the bonding pads BP1 and BP2. As shown in FIG. 16, the bonding pads BP1 and BP2 of the first structure 100 and the second structure 200 are distributed over a wide range of the first structure 100 and the second structure 200. The locations of the bonding pads BP1 and BP2 depend on the size of the SAU region SAUR and/or the dimensions of the shape along the xy-plane, and have no regularity and are randomly distributed.

### 1.2. Advantages (Effects)

According to the first embodiment, as described below, a storage device that enables wiring to be disposed at a large interval is provided.

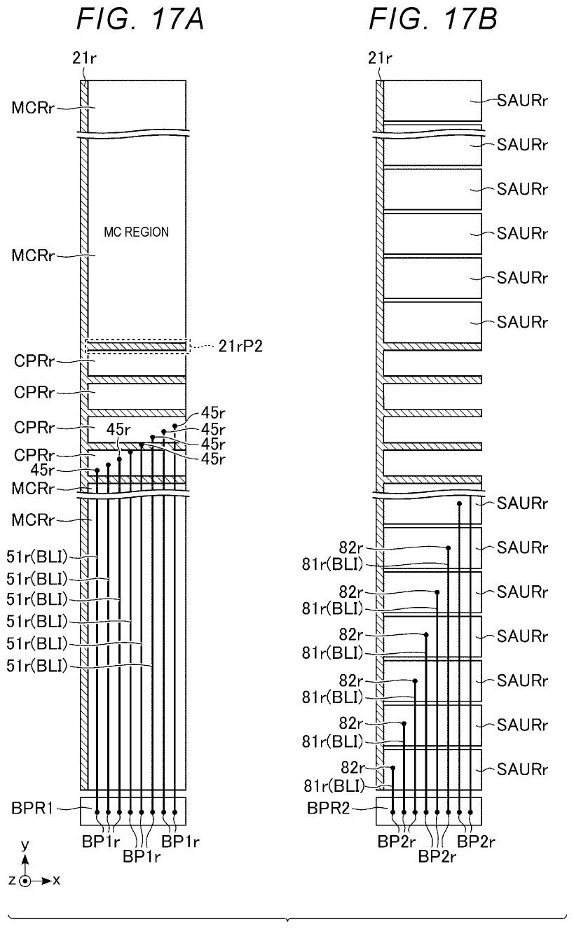

FIGS. 17A and 17B show a layout of a part of a storage device Ir, which is a storage device according to a comparative example, along the xy-plane. The structure shown in FIG. 17A is located in a layer below the structure shown in FIG. 17B. The storage device Ir is provided with a conductor 21r, an MC region MCRr, a CC region CPRr, an SAU region SAURr, conductors 51r and 81r, contacts 82r and 45r, and bonding pads BP1r and BP2r. The conductor 21r, the MC region MCRr, the CC region CPRr, the SAU region SAURr, the conductors 51r and 81r, the contacts 82r and 45r, and the bonding pads BP1r and BP2r correspond to the conductor 21, the MC region MCR, the CC region CPR, the SAU region SAUR, the conductors 51 and 81, the contacts 82 and 45, and the bonding pads BP1 and BP2 of the first embodiment, respectively.

As shown in FIG. 17A, all the CC regions CPRr connected to each conductor 21r are gathered near the center of the portion of the conductors 21r extending in the y-axis. The region at the other position is occupied by the MC region MCRr and is not provided with the CC region CPRr. That is, the group that includes one MC region MCRr, one second portion 21rP2, and one CC region CPRr arranged along the y-axis is not repeatedly arranged along the y-axis.

Each contact in the CC region CPRr is connected to the contact 45r via the same transistor as the transistor T0 of the first embodiment. Each contact 45r is connected to the conductor 51r. All the conductors 51r are in contact with the bonding pad BP1r in the bonding pad region BPR1, reaching a position in the bonding pad region BPR1 from the position of the contact 45r. The bonding pads BP1r are arranged along the x-axis.

As shown in FIG. 17B, the bonding pad BP2r needs to overlap with the bonding pad BP1r in the xy-plane. Therefore, the bonding pad BP2r is also arranged along the x-axis in the bonding pad region BPR2, similarly to the bonding pad BP1r. Each bonding pad BP2r is in contact with one end of the conductor 81r. The other end of each conductor 81r is located in one specific SAU region SAURr, and is connected to the sense amplifier unit SAU via the contact 82r in the SAU region SAURr.

As is clear from FIG. 17A, since the bonding pads BP1r are gathered at one place, all the conductors 51r traverse the MC region MCRr from the position connected to the contact 45r in the vicinity of the CC region CPRr. The number of the conductors 51r is equal to the number of the bit lines BL, and increases to a large number with an increase in the capacity of the storage device. Therefore, the conductors 51r are arranged at a significantly narrow interval. Therefore, a large parasitic capacitance is present between the adjacent conductors 51r.

According to the first embodiment, a group that includes one MC region MCR, one second portion 21P2, and one CC region CPR, which are arranged along the y-axis, is repeatedly provided along the y-axis. The conductor 51 is connected to the sense amplifier unit SAU in the SAU region SAUR, reaching a position in one SAU region SAUR from the position of the contact 45 in the vicinity of the CC region CPR. Therefore, the conductor 51 does not traverse the CC region CPR different from the CC region CPR provided with the contact CP to which the conductor 51 is connected, that is, each conductor 51 is located in a region partitioned by the CC region CPR. Therefore, the occurrence of a region in which all the conductors 51 are arranged along the x-axis is avoided. Therefore, the conductor 51 can be arranged at a large interval. This makes it possible to reduce the parasitic capacitance added to the conductor 51.

### 1.3. Modification Example

The above description relates to an example in which one CC region CPR is provided with only one column of contacts CP arranged along the x-axis. One or a plurality of the CC regions CPR may be provided with two or more columns of the contacts CP arranged along the x-axis.

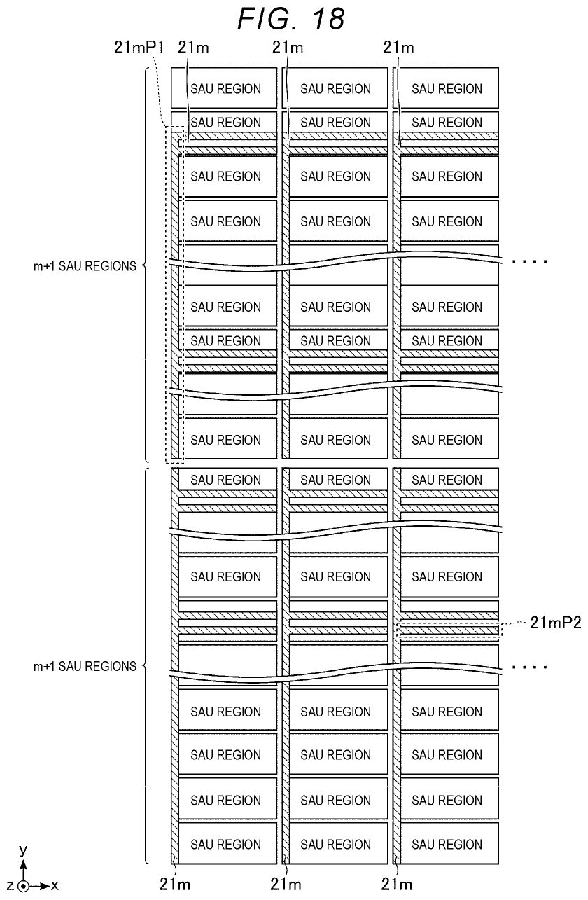

In addition, the above description relates to an example in which only one conductor 21 is provided along a single y-axis direction. As shown in FIG. 18, two or more groups of the conductor 21 and the related structure may be provided along a single y-axis direction. That is, in the example of FIG. 18, two conductors 21m are arranged along each of three y-axis directions. The conductor 21m is provided with a first portion 21mP1 that extends along the y-axis and a plurality of second portions 21mP2 that extend along the x-axis, as in the conductor 21. As a result, the first portion 21mP1 is shorter than the first portion 21P1 of the conductor 21.

In this example, the two conductors 21m arranged along a single y-axis direction are electrically independent. On the other hand, each of the plurality of conductors 21m arranged along the z-axis needs to be connected to one sense amplifier unit SAU. Therefore, the same number of SAU regions SAUR as the number of bit lines BL, that is, m+1 SAU regions SAUR are provided between the imaginary straight line including the upper end of the first portion 21mP1 of each conductor 21m and the imaginary straight line including the lower end of the first portion 21mP1 of each conductor 21m.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A storage device comprising:
a plurality of memory cell regions, each of the plurality of memory cell regions being provided with a semiconductor layer extending in a first direction and a pillar having a side surface in contact with the semiconductor layer and extending in a second direction;
a first conductor provided with a first portion and a plurality of second portions, one of which is in contact with the semiconductor layer, the first portion extending in the first direction, and the plurality of the second portions extending in a third direction and connected to the first portion; and
a plurality of contact regions, each of the plurality of contact regions being provided with a plurality of contacts extending in the second direction, wherein
a plurality of groups is arranged in the first direction when viewed in the second direction, each of groups including one of the plurality of memory cell regions, one of the plurality of second portions, and one of the plurality of contact regions, which are arranged in the first direction when viewed in the second direction.

2. The storage device according to claim 1, wherein one of the plurality of contacts is in contact with the first conductor in each of the plurality of groups.

3. The storage device according to claim 1, wherein one of the plurality of contacts has a side surface in contact with the first conductor in each of the plurality of groups.

4. The storage device according to claim 1, further comprising:
a first sense amplifier unit region provided with a sense amplifier unit;
a first transistor having a first end connected to one of the plurality of contacts and a second end; and
a second conductor having a third end connected to the second end of the first transistor and a fourth end located in the first sense amplifier unit region when viewed in the second direction.

5. The storage device according to claim 4, wherein
the first transistor is spaced apart in the second direction with respect to the plurality of contacts,
the second conductor is spaced apart in the second direction with respect to the first transistor, and
the sense amplifier unit is spaced apart in the second direction with respect to the second conductor.

6. The storage device according to claim 1, wherein N first conductors including the first conductor and N sense amplifier unit regions are provided, where N is an integer of 2 or more.

7. The storage device according to claim 6, wherein the first portion of each first conductor has fifth and sixth ends in the first direction, and
the N sense amplifier unit regions are arranged along the first direction when viewed in the second direction in a region between an imaginary first straight line including the fifth end and an imaginary second straight line including the sixth end.

8. The storage device according to claim 7, further comprising:
a third conductor aligned in the first direction with the first conductor, separated from the first conductor, and provided with a third portion extending in the first direction; and
M second sense amplifier unit regions, where M is an integer of 2 or more, wherein
each of the M second sense amplifier unit regions is provided with the sense amplifier unit,
the third portion of the third conductor has seventh and eighth ends in the first direction, and
the M second sense amplifier unit regions are arranged in the first direction when viewed in the second direction in a region between an imaginary third straight line including the seventh end and an imaginary fourth straight line including the eighth end.

9. The storage device according to claim 1, wherein the pillar includes:
a fourth conductor having a cylindrical shape and extending in the second direction;
a first insulator extending in the second direction and surrounding the fourth conductor;
a second insulator extending in the second direction and surrounding the first insulator; and
a third insulator extending in the second direction, surrounding the second insulator, and being in contact with the semiconductor layer.

10. The storage device according to claim 9, wherein the second insulator is a charge storage layer.

11. A storage device comprising:
a first chip having a plurality of first bonding pads; and
a second chip having a plurality of second bonding pads that are respectively bonded to the plurality of first bonding pads, wherein the first chip includes:
a plurality of memory cell regions, each of the plurality of memory cell regions being provided with a semiconductor layer extending in a first direction and a pillar having a side surface in contact with the semiconductor layer and extending in a second direction;
a first conductor provided with a first portion and a plurality of second portions, one of which is in contact with the semiconductor layer, the first portion extending in the first direction, and the plurality of the second portions extending in a third direction and connected to the first portion; and
a plurality of contact regions, each of the plurality of contact regions being provided with a plurality of contacts extending in the second direction, and
wherein a plurality of groups is arranged in the first direction when viewed in the second direction, each of groups including one of the plurality of memory cell regions, one of the plurality of second portions, and one of the plurality of contact regions, which are arranged in the first direction when viewed in the second direction.

12. The storage device according to claim 11, wherein one of the plurality of contacts is in contact with the first conductor in each of the plurality of groups.

13. The storage device according to claim 11, wherein one of the plurality of contacts has a side surface in contact with the first conductor in each of the plurality of groups.

14. The storage device according to claim 11, wherein
the second chip includes a first sense amplifier unit region provided with a sense amplifier unit, and
the first chip further includes a first transistor having a first end connected to one of the plurality of contacts and a second end, and a second conductor having a third end connected to the second end of the first transistor and a fourth end located in the first sense amplifier unit region when viewed in the second direction.

15. The storage device according to claim 14, wherein
the first transistor is spaced apart in the second direction with respect to the plurality of contacts,
the second conductor is spaced apart in the second direction with respect to the first transistor, and
the sense amplifier unit is spaced apart in the second direction with respect to the second conductor.

16. The storage device according to claim 11, wherein N first conductors including the first conductor and N sense amplifier unit regions are provided, where N is an integer of 2 or more.

17. The storage device according to claim 16, wherein
the first portion of each first conductor has fifth and sixth ends in the first direction, and
the N sense amplifier unit regions are arranged along the first direction when viewed in the second direction in a region between an imaginary first straight line including the fifth end and an imaginary second straight line including the sixth end.

18. The storage device according to claim 17, further comprising:
a third conductor aligned in the first direction with the first conductor, separated from the first conductor, and provided with a third portion extending in the first direction; and
M second sense amplifier unit regions, where M is an integer of 2 or more, wherein
each of the M second sense amplifier unit regions is provided with the sense amplifier unit,
the third portion of the third conductor has seventh and eighth ends in the first direction, and
the M second sense amplifier unit regions are arranged in the first direction when viewed in the second direction in a region between an imaginary third straight line including the seventh end and an imaginary fourth straight line including the eighth end.

19. The storage device according to claim 11, wherein the pillar includes:
a fourth conductor having a cylindrical shape and extending in the second direction;
a first insulator extending in the second direction and surrounding the fourth conductor;
a second insulator extending in the second direction and surrounding the first insulator; and
a third insulator extending in the second direction, surrounding the second insulator, and being in contact with the semiconductor.

20. The storage device according to claim 19, wherein the second insulator is a charge storage layer.
